(19) United States
(12) Patent Application Publication
(10) Pub. No.: US 2012/0205606 A1
(43) Pub. Date: Aug. 16, 2012

(54) Nonvolatile Memory Device Using The Resistive Switching of Graphene Oxide And The Fabrication Method Thereof

(75) Inventors: Sang Wuk Lee, Seoul (KR); Tae Won Kang, Seoul (KR); Gennady Panin, Seoul (KR); Olesya Kapitanova, Seoul (KR)

(73) Assignee: Dongguk University Industry-Academic Cooperation Foundation, Seoul (KR)

(21) Appl. No.: 13/280,818

(22) Filed: Oct. 25, 2011

(30) Foreign Application Priority Data
Feb. 14, 2011 (KR) 10-2011-0012801

(51) Int. Cl. H01L 45/00; H01L 21/8239; B82Y 99/00

(52) U.S. Cl. 257/2; 438/382; 257/E45.001; 977/734; 257/E21.645; 257/E21.004

(57) ABSTRACT

Disclosed are an oxide-based nonvolatile memory with superior resistive switching characteristics and a method for preparing the same. More particularly, the disclosure relates to a nonvolatile memory device having a metal/reduced graphene oxide (r-GO) thin film/metal structure and a method for preparing the same.

### CROSS-REFERENCE TO RELATED APPLICATIONS

This application claims priority under 35 U.S.C. §119 to Korean Patent Application No. 10-2011-0012801, filed on Feb. 14, 2011, in the Korean Intellectual Property Office, the disclosure of which is incorporated herein by reference in its entirety.

### TECHNICAL FIELD

The present disclosure relates to a nonvolatile memory device using the resistive switching of metal oxide and a method for preparing the same, more particularly to a nonvolatile memory device using the resistive switching of reduced graphene oxide (r-GO) thin film and a method for preparing the same.

### BACKGROUND

The discovery of graphene as new two-dimensional crystal consisting of a single layer of carbon atoms has led to a lot of scrutiny of its oxide, i.e. graphene oxide (GO). Graphene oxide is composed of a single layer of graphene with carboxyl, hydroxyl or epoxy groups bound thereto. It was first synthesized in 1859 by Brodie. Recently, it was shown that graphene oxide has very interesting properties.

Graphene oxide is an insulator with a wide band gap (6 eV), but controlled reduction can lead to zero-band gap (0 eV) graphene via complete removal of the C—O bonds. Although it is practically difficult to obtain perfect graphene with reduction only, it is possible to tune the electrical, optical and mechanical properties. Carbon atoms bonded to oxygen are sp³ hybridized and control conductivity by disrupting the extended C—C sp² conjugated network of graphene. Although some people call reduced graphene oxide as graphene, it is a misnomer. In the present disclosure, the graphene oxide with the oxygen content decreased through reduction is defined as reduced graphene oxide (r-GO; reduced-GO).

The solubility of graphene oxide in water and other solvents allows it to be uniformly deposited onto any substrates using simple methods such as drop casting, spin coating, spraying, Langmuir-Blodgett deposition and vacuum filtration, which makes it potentially useful for fabrication of large-scale flexible and transparent devices.

The charge-based memory devices such as dynamic random access memory (DRAM) and flash memory, while being omnipresent today, do have technological and physical limitations as device dimensions have shrunk. As an alternative, resistive random access memory (RRAM) relying upon a switching mechanism based on change in resistance has attracted attentions as a promising next-generation nonvolatile memory (NVM) due to its simple structure, facile processing, high density, high operation speed and long retention time.

The oxide-based RRAM has a metal/insulator/metal (MIM) structure, and the insulator is usually metal oxide. FIG. 1 shows its typical current-voltage (I-V) curve. The operation principle of RRAM is as follows. Initially, the RRAM is in an “off” state, i.e. high-resistance state (HRS). When a specific voltage is applied to the RRAM with the MIM structure in the initial state, switching occurs from the high-resistance state to a low-resistance “on” state (low-resistance state; LRS). This behavior is called “set” and the voltage is called the “set voltage”. Once switched to the “on” state, the state is maintained until another specific voltage is applied, which is called the “reset voltage” and the behavior is called “reset”. To read the memory state, a voltage lower than the reset voltage is applied to prevent the stored memory value from changing. This voltage is called the “reading voltage” (see FIG. 1).

For a general memory device using metal oxide to exhibit resistive switching, a process of polarizing the metal oxide is required. This preliminary process is called forming (or polarization). Usually, a voltage of several volts is applied to the device for seconds or minutes.

To date, various insulating or semiconducting materials have been found to exhibit resistive switching, including chalcogenides, organic materials, amorphous silicon, perovskite oxides such as Pr₁₋ₓCaₓMnO₃ and Cr-doped SrZrO₃, and Fe₃O₄ nanoparticles. In particular, RRAM based on binary transition metal oxide (NiO, TiO₂ and ZnO) particles has been studied a lot. Recently, resistive memory devices using graphene oxide thin film are reported in the academic circle.

The existing resistive switching materials such as metal oxide (NiO, TiO₂, ZnO, etc.) are applicable to highly-integrated memory devices, but are limited in use for flexible substrates because of their rigid properties. Recently, memory devices with a metal/graphene oxide thin film/metal structure using 20-40 nm thick graphene oxide thin film are reported in the academic circle. They are drawing attentions in that fabrication on flexible substrate is possible while providing superior memory performance.

However, the resistive switching characteristics of the memory devices with the metal/graphene oxide thin film/metal structure are greatly dependent on the metal used. Easily oxidized substances such as Al, Ni, Cu and Ti form metal oxide at the interface between graphene oxide and metal during deposition. The metal oxide layer controls on/off of the resistive material in association with diffusion of metal atoms. In contrast, metals that are not oxidized such as Au, Pt and Ag show less or no resistive switching. Thus, if the kind of metals that can be used is restricted, it becomes difficult to control the formation of oxide and also to control the switching voltage characteristics of the memory device.

Therefore, development of a memory device allowing more consistent and stable processing utilizing the bulk properties of the used material, while maintaining high-integration and high-performance properties and allowing fabrication on flexible substrates, with no limitation in the metal that can be used and with no undesired oxide film formed on the interface with the metal, is necessary.

On occasion, devices with simplified function are required at low cost and with simple process. For instance, researches are actively carried out to form electronic circuits for the radio frequency identification (RFID) tag on flexible substrates by printing to reduce cost. However, a memory device suitable for the printing process has not been reported as yet. To be applicable to the printing process, the thickness or width of the structure should be at least 10 μm. It is because the resolution of the currently available inkjet printer is only about 10 μm and that of the screen printer is usually about 0.5 mm.

However, the application of graphene oxide to electronic devices is limited since it is an insulator. When a suspension of graphene oxide is prepared by a modification of the Hummers's method reported in 1958, it exhibits a slight conductivity due to the presence of conductive graphite or graphene. However, since the conductivity is not sufficient, the inter-electrode gap in a device using graphene is 20-40 nm. Thus, development of a resistive memory device which can be fabricated on flexible substrates, can operate with an electrode gap of 20-40 nm so as to utilize the semiconductor process as well as with an electrode gap of 10 μm or 0.5 mm or larger so as to utilize the printing process, and is mass-producible by an inexpensive printing process is required.

### SUMMARY

The present disclosure is directed to providing a nonvolatile memory device with superior resistive switching characteristics, which can be fabricated on flexible substrates, can be processed stably by using the bulk properties of the used material, and can be produced by an inexpensive printing process with no limitation in electrode gap, while maintaining the high-performance and high-integration properties of the existing resistive memory devices and without limitation in the kind of metal that can be used, and a method for preparing the same.

In one general aspect, the present disclosure provides a nonvolatile memory device having metal/reduced graphene oxide (r-GO) thin film/metal planar structure, including: two metal terminals provided on a substrate; and a reduced graphene oxide thin film formed on or below the two metal terminals and connecting the two metal terminals.

In another general aspect, the present disclosure provides a method for fabricating a nonvolatile memory device having metal/reduced graphene oxide (r-GO) thin film/metal planar structure, including steps of: 1) patterning two metal electrodes on a substrate; 2) forming a graphene oxide thin film on the two metal electrodes to connect the metal electrodes; and 3) reducing the graphene oxide thin film.

In another general aspect, the present disclosure provides another method for fabricating a nonvolatile memory device having metal/reduced graphene oxide (r-GO) thin film/metal planar structure, including steps of: 1) forming a graphene oxide thin film on a substrate; 2) reducing the graphene oxide thin film; and 3) patterning two metal electrodes on the reduced graphene oxide thin film.

Other features and aspects will be apparent from the following detailed description, the drawings, and the claims.

### BRIEF DESCRIPTION OF THE DRAWINGS

The above and other objects, features and advantages of the present disclosure will become apparent from the following description of certain exemplary embodiments given in conjunction with the accompanying drawings, in which:

FIG. 1 shows an operation principle of RRAM (“On” state and “off” state are shown in the figure);

FIG. 2 shows a nonvolatile memory device having a planar structure according to an embodiment [(a) and (b) are functionally identical but different in stacking order. In (c), an upper metal electrode is provided on the nonvolatile memory device of (a) in order to increase the degree of integration.];

FIG. 3 shows transmission electron microscopic (TEM) images of graphene oxide (GO) flakes;

FIG. 4 shows TEM images and selected area electron diffraction (SAED) patterns of a graphene oxide (GO) single layer;

FIG. 5 shows an atomic force microscopic (AFM) image and a thickness profile of a graphene oxide (GO) single layer;

FIG. 6 shows Raman spectra of a graphene oxide (GO) film;

FIG. 7 shows an optical image of a nonvolatile memory device fabricated according to an embodiment using a reduced graphene oxide (r-GO) thin film mounted on a chip holder for measurement;

FIG. 8 shows I-V curves of a nonvolatile memory device fabricated according to an embodiment using a reduced graphene oxide (r-GO) thin film;

FIG. 9 shows an I-V curve of a nonvolatile memory device fabricated according to an embodiment using a reduced graphene oxide (r-GO) thin film when the forming voltage is 5 V, demonstrating switching behaviors; and

FIG. 10 shows scanning electron microscopic (SEM) images and an induced current profile as an electron beam induced current (EBIC) analysis result of resistive switching with a spatial resolution of a nonvolatile memory device fabricated according to an embodiment using a reduced graphene oxide (r-GO) thin film.

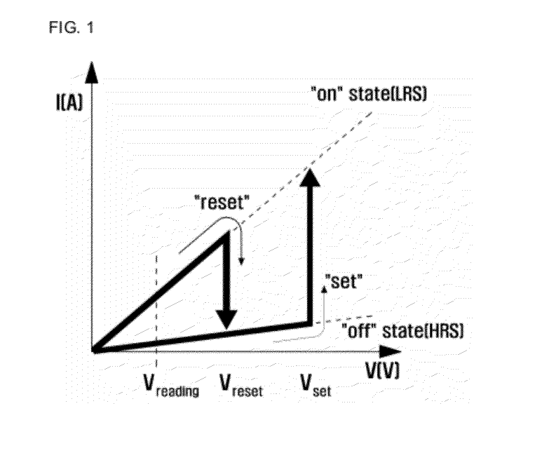

### DETAILED DESCRIPTION OF EMBODIMENTS

The advantages, features and aspects of the present disclosure will become apparent from the following description of the embodiments with reference to the accompanying drawings, which is set forth hereinafter. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. The terminology used herein is for the purpose of describing particular embodiments only and is not intended to be limiting of the example embodiments. As used herein, the singular forms “a”, “an” and “the” are intended to include the plural forms as well, unless the context clearly indicates otherwise. It will be further understood that the terms “comprises” and/or “comprising”, when used in this specification, specify the presence of stated features, integers, steps, operations, elements, and/or components, but do not preclude the presence or addition of one or more other features, integers, steps, operations, elements, components, and/or groups thereof.

Hereinafter, exemplary embodiments will be described in detail with reference to the accompanying drawings.

In one general aspect, the present disclosure provides a nonvolatile memory device having metal/reduced graphene oxide (r-GO) thin film/metal planar structure, including: two metal terminals provided on a substrate; and a reduced graphene oxide thin film formed on or below the two metal terminals and connecting the two metal terminals.

In an exemplary embodiment, when the reduced graphene oxide thin film is formed on the metal terminals, a further metal terminal is provided on the graphene oxide thin film to form a vertical structure.

In an exemplary embodiment, the substrate is an insulating substrate selected from a crystalline substrate, an amorphous substrate and a plastic substrate. Specifically, it may be, for example, a silicon oxide substrate, a sapphire substrate, a glass substrate, a PET substrate, a polyimide substrate, a ceramic substrate, etc.

In an exemplary embodiment, the gap between the metal terminals is from 20 nm to 2 mm, and the thickness of the reduced graphene oxide thin film is from 0.7 nm to 1 μm.

In an exemplary embodiment, a resistive switching voltage is from 0.5 V to 30 V, specifically 0.7 V, and an on/off current ratio is about 1,000. The switching voltage may be determined depending on the degree of reduction of the reduced graphene oxide thin film and the gap between the two electrodes.

In another general aspect, the present disclosure provides a method for fabricating a nonvolatile memory device having metal/reduced graphene oxide (r-GO) thin film/metal planar structure, including steps of: 1) patterning two metal electrodes on a substrate; 2) forming a graphene oxide thin film on the two metal electrodes to connect the metal electrodes; and 3) reducing the graphene oxide thin film.

In an exemplary embodiment, a step of 4) patterning an upper metal electrode on the reduced graphene oxide thin film is further included.

In another general aspect, the present disclosure provides another method for fabricating a nonvolatile memory device having metal/reduced graphene oxide (r-GO) thin film/metal planar structure, including steps of: 1) forming a graphene oxide thin film on a substrate; 2) reducing the graphene oxide thin film; and 3) patterning two metal electrodes on the reduced graphene oxide thin film.

In an exemplary embodiment, the graphene oxide is prepared by: a) mixing graphite with sodium nitrate (NaNO₃) and sulfuric acid (H₂SO₄) and oxidizing the same by adding potassium permanganate (KMnO₄); b) keeping the mixture at room temperature for 3 days so that the graphite is exfoliated and forms graphene oxide flakes; and c) washing the mixture with dilute sulfuric acid and hydrogen peroxide or hydrogen peroxide and water and purifying the same by centrifugation.

In an exemplary embodiment, when the substrate and the metal electrode are made of materials that can endure high temperatures, the reduction may be performed by annealing at 800-1,000° C. for 5-60 minutes under Ar/H₂ mixture (90% Ar, 10% H₂) atmosphere. Alternatively, when the substrate is made of plastic, the reduction may be performed by adding ascorbic acid to a suspension of graphene oxide (GO) so as to form the graphene oxide thin film and annealing at 130-300° C. for 6-24 hours under Ar atmosphere. The heating temperature and time may be different depending on the desired degree of reduction of the graphene oxide thin film. The higher the temperature and the longer the heating time, is greater the degree of reduction.

In an exemplary embodiment, the conductivity of the reduced graphene oxide thin film is adjusted during the reduction of the graphene oxide thin film so as to control the switching voltage of the memory device.

In an exemplary embodiment, the graphene oxide thin film is formed by a method selected from spin coating, inkjet printing, screen printing, spin casting, spraying and filtering of a suspension of graphene oxide, and the metal electrode is patterned by photolithography, shadow masking, inkjet printing, screen printing or offset printing after forming a metal layer by a method selected from e-beam deposition, thermal evaporation and chemical vapor deposition.

In an exemplary embodiment, the metal electrode is made of at least one selected from the group consisting of Ti, Al, Cu, W, Fe, Sn, Au, Ag, Pt, and graphene.

### EXAMPLES

The examples and experiments will now be described. The following examples and experiments are for illustrative purposes only and not intended to limit the scope of this disclosure.

The present disclosure is based on the resistive switching in a metal/reduced graphene oxide (r-GO) thin film/metal structure. The reduced graphene oxide (r-GO) is prepared from a suspension of graphene oxide (GO). The graphene oxide is synthesized by a modified Hummers's method using graphite powder or graphite rod. The structure according to the present disclosure is fabricated by patterning electrodes and spin coating the suspension of graphene oxide (GO) on a SiO₂/Si substrate and then reducing the same. In the absence of a pre-forming process, the structure according to the present disclosure exhibits a conductor-like non-rectifying behavior. After a pre-forming process, it exhibits a diode-like rectifying behavior.

Although the inter-electrode gap cannot be extended to hundreds of nm in the existing memory device, a memory device having the metal/reduced graphene oxide (r-GO) thin film/metal structure according to the present disclosure can operate not only with an inter-electrode gap of tens of nm, but also in the order of μm or larger. To demonstrate this, the inter-electrode gap is increased to 25 μm in the following examples and the mechanism of resistive switching in the reduced graphene oxide (r-GO) thin film is investigated.

Electron beam induced current (EBIC) measurement in high-resolution scanning electron microscopy (HRSEM) reveals that a potential barrier is formed at the reduced graphene oxide (r-GO)/metal interface. When a bias voltage is applied, the barrier disappears locally, resulting in resistive switching (RS). Microscopically, the resistive switching behavior originates from the formation and depletion of conductive filaments near the reduced graphene oxide (r-GO)/metal interface that arise from reversible diffusion of negatively charged oxygen ions and formation of sp³ and sp² clusters during the set and reset processes, respectively.

### Example 1

### Synthesis of Graphene Oxide (GO)

Graphene oxide or graphene oxide platelets are synthesized by the modified Hummers's method from graphitic rods. There is a difference in that the original Hummers's method uses graphite powder and lacks the procedure of exfoliation and graphene oxide purification. The modified method is more effective for purification of the reaction product. Specifically, the graphene oxide synthesis scheme is as follows:

(1) KMnO₄ is added to a mixture of graphite+NaNO₃+H₂SO₄ (T=0° C.).

(2) The mixture is kept at room temperature for 3 days.

(3) After diluting the mixture by adding hydrogen peroxide (H₂O₂, 30%) and dilute sulfuric acid (H₂SO₄, 5%), dilute sulfuric acid (3%) and dilute hydrogen peroxide (0.5%) are further added and ions are removed by centrifugation.

In the step (1), an oxide layer is intercalated into graphite as a result of interaction among the graphite, sodium nitrate and sulfuric acid, which promotes the oxidation of graphite by potassium permanganate. In the step (2), the mixture is exposed for a few days to induce expansion of graphite as well as exfoliation of the oxidized graphite to form thin graphene oxide platelets. In the step (3), manganese oxide is got rid of. Following centrifugation at least 15 times, the reaction product is completely removed by washing the mixture with hydrogen peroxide and water at least 20 times.

### Example 2

### Fabrication of Nonvolatile Memory Device

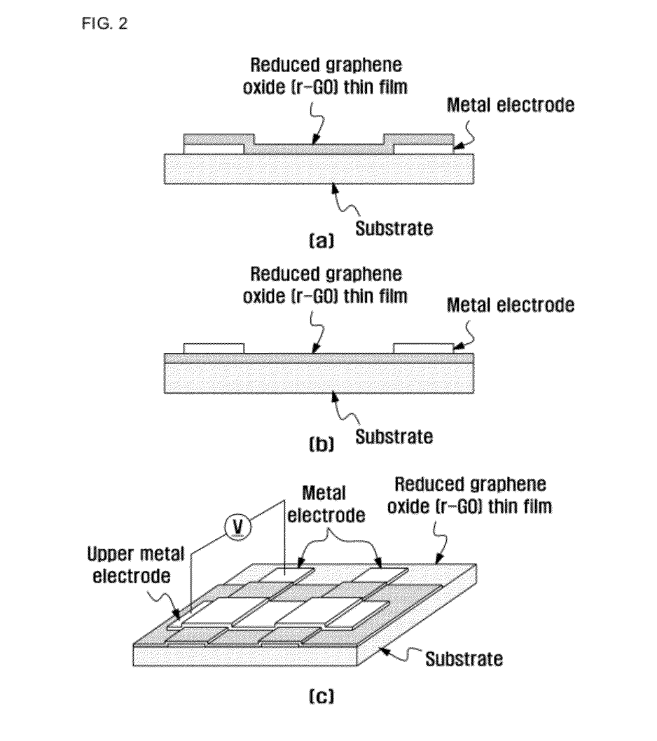

A nonvolatile memory device having a metal/reduced graphene oxide (r-GO) thin film/metal structure according to the present disclosure is schematically shown in FIG. 2 (a). Metal electrodes are formed in parallel on a substrate, and a reduced graphene oxide (r-GO) thin film is formed on the electrodes.

The substrate may be any insulating substrate, e.g. a single crystal substrate such as a silicon substrate or a sapphire substrate, a flexible plastic substrate such as a PET substrate or a polyimide substrate, an amorphous substrate such as a glass substrate or a ceramic substrate, or the like. In this example, a silicon substrate on which a silicon oxide film is grown (SiO₂/Si) is used.

The metal electrodes may patterned by photolithography or using a shadow mask after depositing a thin metal film by a method selected from e-beam deposition, thermal evaporation and chemical vapor deposition. Alternatively, the electrodes may be formed by inkjet printing with a conductive ink or by screen printing with a conductive paste. In this example, the electrodes are formed by photolithography after depositing aluminum by e-beam deposition.

The metal electrode may be made of a metal which is oxidized or a metal which is not oxidized. Graphene may be used as the metal electrode. Metals which could be oxidized are Ti, Al, Cu, W, Fe, Sn etc. Metals which could not be oxidized are Au, Ag, and Pt. In an exemplary embodiment, the metal electrode is made of at least one selected from the group consisting of Ti, Al, Cu, W, Fe, Sn, Au, Ag, Pt, and graphene.

The gap between the metal electrodes may be from 20 nm at which patterning is possible to 0.5 mm at which printing can be applied. When the inter-electrode gap is smaller than 20 nm, metal atoms may diffuse and result in interference. Thus, it is desirable that the gap is 20 nm or larger. Although there is no upper limit of the gap, a recommended maximum gap is 2 mm because the resolution of manual printing is usually within 1 mm. The gap between the metal electrodes has a great effect on the switching voltage of the memory device. In this example, the gap is set at 25 μm. In general, the larger the inter-electrode gap, the higher is the switching voltage, and vice versa.

After the electrodes are formed, the graphene oxide thin film is formed on the metal electrode to complete the structure of the nonvolatile memory device. This simple structure is applicable to the printing process. The graphene oxide thin film may be formed by spin coating, inkjet printing or spraying a suspension of graphene oxide directly on the metal electrodes and then drying. Alternatively, after forming the graphene oxide thin film on another substrate, it may be attached onto the metal electrodes, by spin casting or vacuum filtering.

The thickness of the graphene oxide thin film may be from 0.7 nm to 1 μm, depending on the concentration of the suspension and the number of revolutions of the spin coating. The thickness of 0.7 nm means 1 layer of graphene oxide. In this example, a thin film with a thickness of 50-100 nm is formed.

In FIG. 2 (b), a device with a different stacking order is shown. A graphene oxide thin film is formed on a substrate first, and then metal electrodes are formed thereon. Since the bulk properties of the reduced graphene oxide (r-GO) thin film are used, the operation characteristics of the device are the same as those of FIG. 2 (a), in spite of the difference in stacking order.

In FIG. 2 (c), an upper metal electrode is formed on the reduced graphene oxide (r-GO) thin film of FIG. 2 (a). As a result, two identical devices are obtained on the same area. This structure may be applied to RRAM with high device density.

### Example 3

### Reduction of Graphene Oxide

Ascorbic acid is added to a suspension of graphene oxide to form a graphene thin film, which is reduced by heating annealing at 130-300° C. for 6-24 hours under Ar atmosphere. Graphene oxide, which is an insulator, is partially reduced to form sp² bonding, exhibiting conductivity. Consequently, the conductivity of the graphene oxide thin film changes with heating temperature and time. In this example, the reduction is performed at 200° C. for 12 hours under Ar atmosphere.

Alternatively, the reduction of the graphene oxide thin film may be performed by annealing at 800-1,000° C. for 5-60 minutes under Ar/H₂ mixture (90% Ar, 10% H₂) atmosphere. In this case, the substrate and the metal electrode of the memory device should be able to endure the high temperature.

In general, the reduction is completed quickly at higher temperature. In accordance with the present disclosure, the degree of reduction of the graphene oxide thin film may be adjusted depending on the inter-electrode gap so as to control the switching voltage.

### Test Example

### Characterization of Graphene Oxide (GO) Flakes and Thin Films

TEM, SAED and AFM

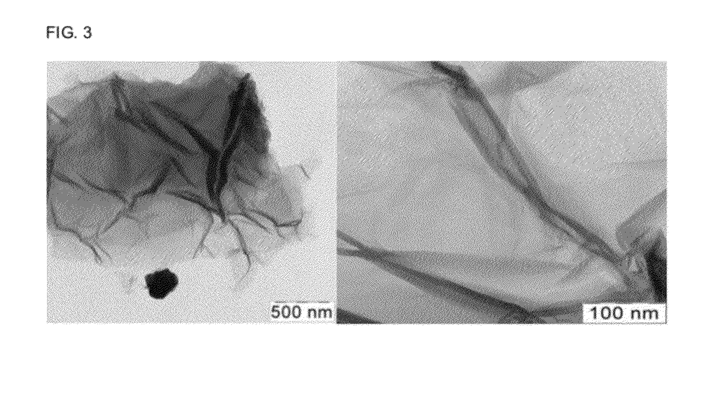

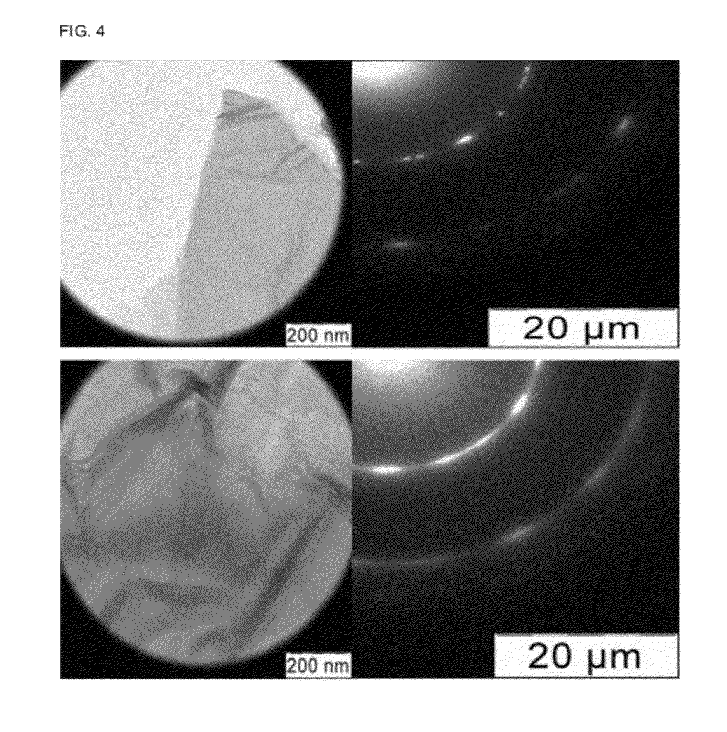

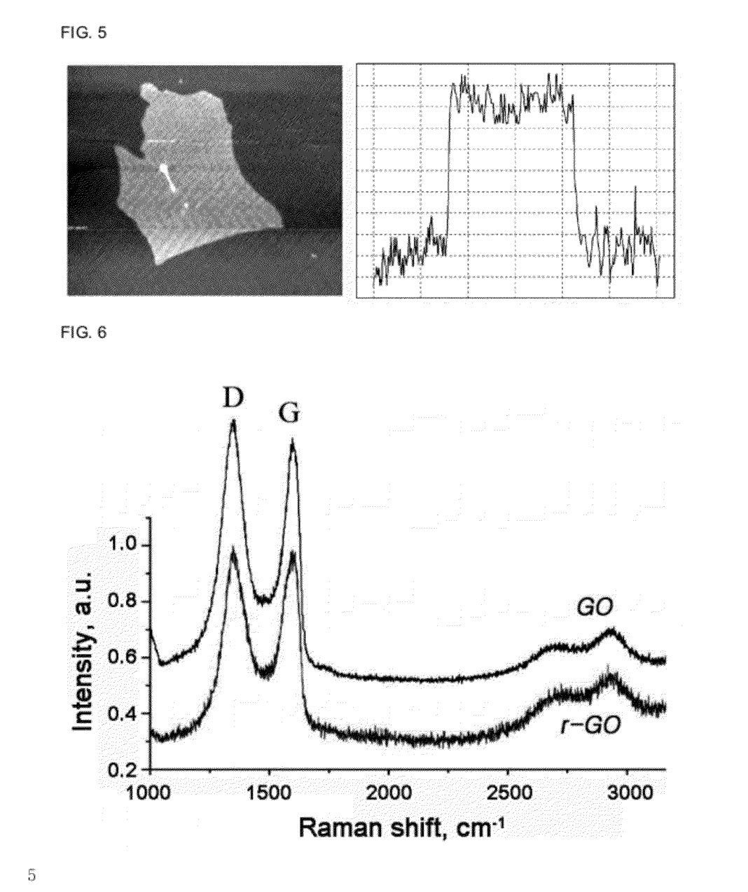

As seen from FIGS. 3 and 4, the resulting graphene oxide (GO) is well-exfoliated. The flakes are usually a few layers thick and several tens of micrometers in diameter. The thickness is in the range of 1-1.4 nm as seen from the AFM profile of FIG. 5. The electron diffraction shows both crystalline and amorphous patterns in different parts of the flakes, indicating their spatially inhomogeneous electronic properties.

Raman Spectra

The Raman spectra of FIG. 6 show the characteristics of graphene oxide (GO, sp³ bonding) D (1357 cm⁻¹) and graphene (sp² bonding) G (1578 cm⁻¹) before and after the reduction of graphene oxide. After the reduction, the ratio of intensities of peak D to peak G increases. It is attributable to a decrease in the density of defects and change in the ratio of sp² to sp³ clusters

I-V Measurement

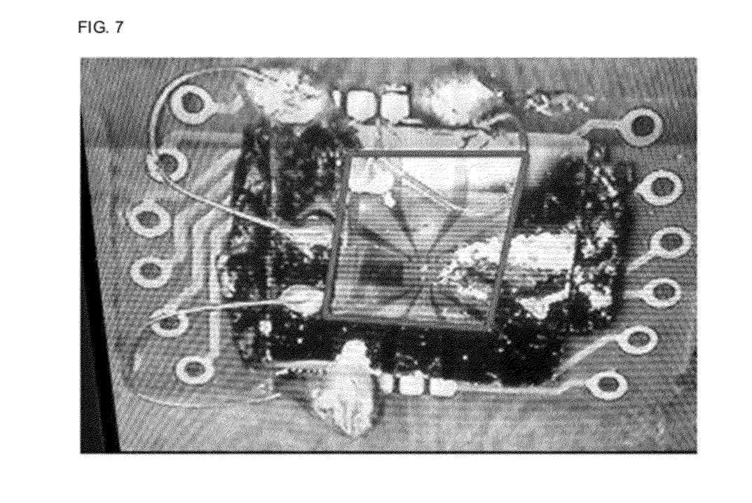

FIG. 7 shows an optical image of the nonvolatile memory device fabricated in the foregoing example (FIG. 2 (a)) mounted on a chip holder for measurement.

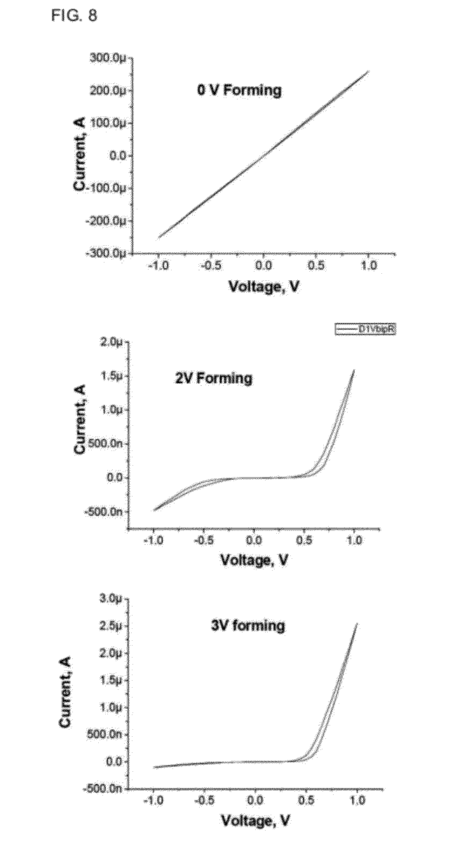

FIG. 8 shows current-voltage (I-V) curves of the nonvolatile memory device fabricated in the foregoing example, having a metal/reduced graphene oxide (r-GO)/metal structure with an inter-electrode gap of 25 μm, when the bias voltage is swept from 0 V to 1 V, back from 1 V to −1 V, and then again from −1 V to 0 V. The forming step is a preliminary step of applying a constant voltage to the electrode prior to normal operation of an oxide-based memory device so as to polarize the oxide. When the bias voltage is applied without the forming voltage (0 V forming), a conductor-like I-V behavior is observed with no effect of a memory device, although the hysteresis curve in the positive and negative bias ranges reflect a slight bipolar switching behavior.

When the forming voltage is 2 V, the current hysteresis is distinctly different when the bias voltage changes from 0 to 1 V and when it changes from 1 to 0 V. Although a bipolar switching behavior is observed with hysteresis curves occurring in both positive and negative bias voltages, they are not symmetrical but the hysteresis in the positive bias is more distinct, reflecting a slight unipolar switching effect.

When the forming voltage is 3 V, a unipolar switching behavior is observed with the memory effect occurring only in the positive bias.

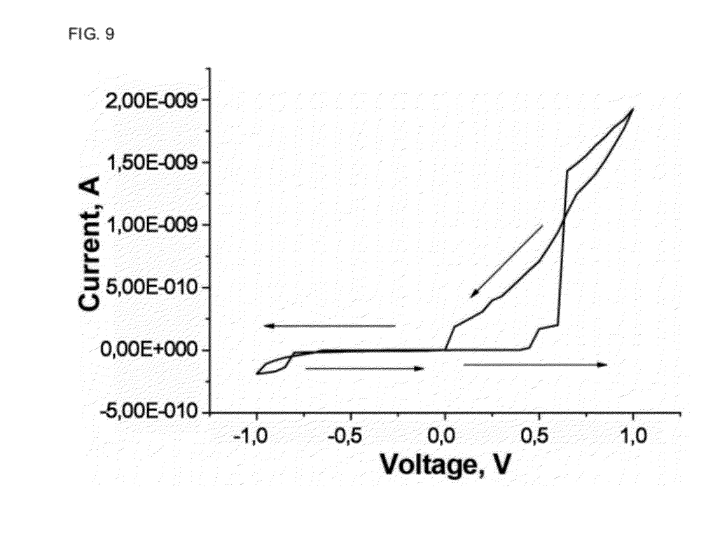

FIG. 9 shows an I-V curve of when the forming voltage is 5 V. An abrupt switching behavior is observed at the constant bias voltage. The on/off current ration during the switching of the nonvolatile memory device is about 1000.

The switching voltage depends greatly on the inter-electrode gap, the thickness of the reduced graphene oxide (r-GO) thin film and the degree of reduction of graphene oxide, and can be controlled in the range from about 0.5 V to about 30 V. The switching voltage of the nonvolatile memory device according to the foregoing example is 0.7 V. It is to be noted that, whereas the switching voltage of the existing metal oxide-based memory device with an inter-electrode gap of 20-40 nm is about 1 V, the switching voltage of the memory device of this example is 0.7 V although the inter-electrode gap is as large as 25 μm.

Electron Beam Induced Current (EBIC) Analysis of Resistive Switching

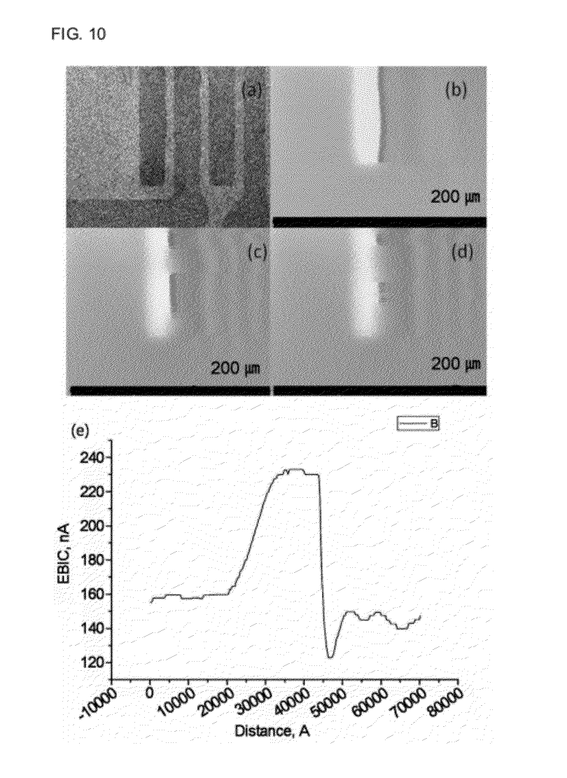

FIG. 10 (a) shows an SEM image of the nonvolatile memory device fabricated in the foregoing example at the reduced graphene oxide (r-GO)/electrode interface (The dark areas are the electrodes, and the narrow region between them is the reduced graphene oxide.). Also shown are SEM images of the nonvolatile memory device at different bias voltages of 0 V (b), 0.5 V (c) and 1 V (d) after pre-forming at 5 V for a while.

The induced current mode reveals the occurrence of induced current by the built-in electric field formed during the pre-forming process. When the bias voltage is 0 V [FIG. 10 (b)], currents are observed in both directions (bright and dark regions) of the electric field formed by the forming process. The bright region corresponds to the positively polarized electrodes, and the dark region corresponds to the reduced graphene oxide thin film. The current distribution is confirmed by the current distribution curve at the electrode interface.

FIG. 10 (e) shows the current measured at the positive electrode/reduced graphene oxide (r-GO) thin film interface when the bias voltage is 0 V. The current is higher in the left electrode region, and it is also observed in the right reduced graphene oxide region. The graph shows that the induced current depends on the direction and intensity of the electric field. The 1 μm-thick zone with particularly low current at the metal/reduced graphene oxide (r-GO) interface reveals the formation of an energy barrier preventing current flow. To summarize, when the bias voltage is applied without a forming process, the memory device exhibits a conductor-like behavior, not the memory behavior. However, after the forming process, an energy barrier is formed at the interface of the positive electrode and the reduced graphene oxide (r-GO).

This contrasts with the metal/graphene oxide/metal structure where an easily oxidized metal such as Al, Ni, Cu, etc. is used, so that metal oxide is formed at the interface with a graphene oxide thin film having oxygen-containing groups such as epoxy, carboxyl, etc., resulting in the formation of an energy barrier without the forming process.

The energy barrier collapses partially when the bias voltage is 0.5 V [FIG. 10 (c)] and completely when the bias voltage is 1 V [FIG. 10 (d)]. As a result, the device is in a low-resistance state (LRS). When a bias voltage of opposite direction is applied, the energy barrier is observed again. It can be said that the formation and modification of the energy barrier during the pre-forming process by the bias voltage has a great effect on resistive switching.

Model of Resistive Switching

Since the reduced graphene oxide (r-GO) consists of sp² clusters in the oxygen-rich sp³ matrix, it exhibits a high-resistance state. In sufficiently high electric field, the sp³ and sp² clusters are reversibly rearranged locally, leading to the low-resistance state.

The pre-forming process, i.e. the polarization process, leads to the formation of energy barrier near the electrode, and it is apparently associated with the sp³ phase rearrangement. The bias voltage results in the diffusion of oxygen and the formation of sp² filaments, which lead to the switching structure in the low-resistance state. A reverse bias results in the reconstruction of isolated sp³ clusters and the high-resistance state. This also evidences that the bulk properties of the reduced graphene oxide (r-GO) thin film are utilized in the present disclosure.

This contrasts with the existing metal oxide-based memory device wherein an insulating metal oxide layer is formed at the metal/graphene oxide interface and metal atoms migrate through the insulating layer to form conductive filaments. That is to say, in the existing metal oxide-based memory device, the insulating layer formed at the metal/graphene oxide interface is utilized rather than the bulk property of the graphene oxide itself.

In summary, resistive switching of the metal/reduced graphene oxide (r-GO) thin film/metal structure is observed at room temperature. In the absence of the pre-forming process, a conductor-like behavior or a slight bipolar switching behavior is detected. The forming process leads to an abrupt change in the device structure, leading to the formation of a strong energy barrier at the interface of the positively biased electrode and the reduced graphene oxide (r-GO) and the memory behavior, which is confirmed by the induced current method. Then, a forward bias voltage results in a low-resistance state of the structure. When a reverse bias voltage is applied, the structure returns to the high-resistance state. It is thought that rearrangement of the cluster structure near the electrode is responsible for the resistive switching.

Although the resistive switching of graphene oxide was reported previously, it is based on oxide film formed between the electrode and the graphene oxide layer and the resistive switching effect occurs without the pre-forming process. The present disclosure is basically different therefrom in that the bulk property of the reduced graphene oxide (r-GO) is used and the pre-forming process is necessary.

The nonvolatile memory device having a metal/reduced graphene oxide (r-GO) thin film/metal structure according to the present disclosure has superior resistive switching characteristics, can be fabricated on flexible substrates because of the thin structure, can be processed stably by using the bulk properties of the used material, and can be produced by an inexpensive printing process as well as a semiconductor process with no limitation in electrode gap, while maintaining the high-performance and high-integration properties and without limitation in the kind of metal that can be used. Accordingly, it may be used to fabricate high-performance, high-integration devices such as RRAM by the semiconductor process or to produce inexpensive RRAM or flexible RFID at low cost in large scale by the printing process.

While the present disclosure has been described with respect to the specific embodiments, it will be apparent to those skilled in the art that various changes and modifications may be made without departing from the spirit and scope of the disclosure as defined in the following claims.

What is claimed is:

1. A nonvolatile memory device having metal/reduced graphene oxide (r-GO) thin film/metal planar structure, comprising:
two metal terminals provided on a substrate; and
a reduced graphene oxide thin film formed on or below the two metal terminals and connecting the two metal terminals.

2. The nonvolatile memory device according to claim 1, wherein, when the reduced graphene oxide thin film is formed on the metal terminals, a further metal terminal is provided on the graphene oxide thin film to form a vertical structure.

3. The nonvolatile memory device according to claim 1, wherein the substrate is an insulating substrate selected from a crystalline substrate, an amorphous substrate and a plastic substrate.

4. The nonvolatile memory device according to claim 3, wherein the substrate is selected from a silicon oxide substrate, a sapphire substrate, a glass substrate, a PET substrate, a polyimide substrate and a ceramic substrate.

5. The nonvolatile memory device according to claim 1, wherein the gap between the metal terminals is from 20 nm to 2 mm.

6. The nonvolatile memory device according to claim 1, wherein the thickness of the reduced graphene oxide thin film is from 0.7 nm to 1 μm.

7. The nonvolatile memory device according to claim 1, wherein a resistive switching voltage is from 0.5 V to 30 V.

8. A method for fabricating a nonvolatile memory device having metal/reduced graphene oxide (r-GO) thin film/metal planar structure, comprising:
patterning two metal electrodes on a substrate;
forming a graphene oxide thin film on the two metal electrodes to connect the metal electrodes; and
reducing the graphene oxide thin film.

9. The method for fabricating a nonvolatile memory device according to claim 8, which further comprises:
patterning an upper metal electrode on the reduced graphene oxide thin film.

10. A method for fabricating a nonvolatile memory device having metal/reduced graphene oxide (r-GO) thin film/metal planar structure, comprising:
forming a graphene oxide thin film on a substrate;
reducing the graphene oxide thin film; and
patterning two metal electrodes on the reduced graphene oxide thin film.

11. The method for fabricating a nonvolatile memory device according to claim 8, wherein the graphene oxide is prepared by: mixing graphite with sodium nitrate (NaNO₃) and sulfuric acid (H₂SO₄) and oxidizing the same by adding potassium permanganate (KMnO₄); keeping the mixture at room temperature for 3 days so that the graphite is exfoliated and forms graphene oxide flakes; and washing the mixture with dilute sulfuric acid and hydrogen peroxide or hydrogen peroxide and water and purifying the same by centrifugation.

12. The method for fabricating a nonvolatile memory device according to claim 8, wherein, when the substrate and the metal electrode are made of materials that can endure high temperatures, the reduction is performed by annealing at 800-1,000° C. for 5-60 minutes under Ar/H₂ mixture (90% Ar, 10% H₂) atmosphere.

13. The method for fabricating a nonvolatile memory device according to claim 8, wherein, when the substrate is made of plastic, the reduction is performed by adding ascorbic acid to a suspension of graphene oxide (GO) so as to form the graphene oxide thin film and annealing at 130-300° C. for 6-24 hours under Ar atmosphere.

14. The method for fabricating a nonvolatile memory device according to claim 8, wherein the conductivity of the reduced graphene oxide thin film is adjusted during the reduction of the graphene oxide thin film so as to control the switching voltage of the memory device.

15. The method for fabricating a nonvolatile memory device according to claim 8, wherein the graphene oxide thin film is formed by a method selected from spin coating, inkjet printing, screen printing, spin casting, spraying and filtering of a suspension of graphene oxide.

16. The method for fabricating a nonvolatile memory device according to claim 8, wherein the metal electrode is patterned by photolithography, shadow masking, inkjet printing, screen printing or offset printing after forming a metal layer by a method selected from e-beam deposition, thermal evaporation and chemical vapor deposition.

17. The method for fabricating a nonvolatile memory device according to claim 8, wherein the gap between the metal electrodes is from 20 nm to 2 mm.

18. The method for fabricating a nonvolatile memory device according to claim 8, wherein the metal electrode is made of at least one selected from the group consisting of Ti, Al, Cu, W, Fe, Sn, Au, Ag, Pt, and graphene.

19. The method for fabricating a nonvolatile memory device according to claim 10, wherein the graphene oxide is prepared by: mixing graphite with sodium nitrate (NaNO₃) and sulfuric acid (H₂SO₄) and oxidizing the same by adding potassium permanganate (KMnO₄); keeping the mixture at room temperature for 3 days so that the graphite is exfoliated and forms graphene oxide flakes; and washing the mixture with dilute sulfuric acid and hydrogen peroxide or hydrogen peroxide and water and purifying the same by centrifugation.

20. The method for fabricating a nonvolatile memory device according to claim 10, wherein, when the substrate and the metal electrode are made of materials that can endure high temperatures, the reduction is performed by annealing at 800-1,000° C. for 5-60 minutes under Ar/H₂ mixture (90% Ar, 10% H₂) atmosphere.

21. The method for fabricating a nonvolatile memory device according to claim 10, wherein, when the substrate is made of plastic, the reduction is performed by adding ascorbic acid to a suspension of graphene oxide (GO) so as to form the graphene oxide thin film and annealing at 130-300° C. for 6-24 hours under Ar atmosphere.

22. The method for fabricating a nonvolatile memory device according to claim 10, wherein the conductivity of the reduced graphene oxide thin film is adjusted during the reduction of the graphene oxide thin film so as to control the switching voltage of the memory device.

23. The method for fabricating a nonvolatile memory device according to claim 10, wherein the graphene oxide thin film is formed by a method selected from spin coating, inkjet printing, screen printing, spin casting, spraying and filtering of a suspension of graphene oxide.

24. The method for fabricating a nonvolatile memory device according to claim 10, wherein the metal electrode is patterned by photolithography, shadow masking, inkjet printing, screen printing or offset printing after forming a metal layer by a method selected from e-beam deposition, thermal evaporation and chemical vapor deposition.

25. The method for fabricating a nonvolatile memory device according to claim 10, wherein the gap between the metal electrodes is from 20 nm to 2 mm.

26. The method for fabricating a nonvolatile memory device according to claim 10, wherein the metal electrode is made of at least one selected from the group consisting of Ti, Al, Cu, W, Fe, Sn, Au, Ag, Pt, and graphene.
